(19) United States
(12) Patent Application Publication
(10) Pub. No.: US 2005/0236650 A1
(43) Pub. Date: Oct. 27, 2005

(54) Array device with switching circuits bootstrap capacitors

(75) Inventors: Martin J. Edwards, Crawley (GB); John R.A. Ayres, Reigate (GB)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: koninkliojke phillips electronics n.c.

(21) Appl. No.: 10/522,847

(22) PCT Filed: Jul. 16, 2003
(86) PCT No.: PCT/IB03/03220

§ 371 Date: Jan. 28, 2005

(30) Foreign Application Priority Data
Jul. 31, 2002 (GB) 0217709.5

(51) Int. Cl. H01L 27/10

(52) U.S. Cl. 257/203

(57) ABSTRACT

An array device has switching circuits in each pixel for selectively routing one of at least two inputs to a pixel element. Switching transistors are connected between a respective one of the at least two inputs and the pixel element. The timing of the operation of the switching transistors is determined in dependence on the data waveform of at least one of the inputs, and a capacitive connection is provided between the gate of at least one of the switching transistors and an output of the switching transistor. This enables a reduction in the data voltage range which is required to ensure that the switching transistors switch correctly, by using a bootstrapping technique. In particular, by controlling the timing of application of the data signals for switching on or off the switching transistors, the voltage levels of at least one of the input signals can be used to provide capacitive coupling through the respective switching transistor onto the bootstrapping capacitor.

This invention relates to switching circuits for use in array devices, particularly but not exclusively for use in pixels of active matrix display devices.

Active matrix displays typically comprise an array of pixels arranged in rows and columns. Each row of pixels shares a row conductor which connects to the gates of the thin film transistors of the pixels in the row. Each column of pixels shares a column conductor, to which pixel drive signals are provided. The signal on the row conductor determines whether the transistor is turned on or off, and when the transistor is turned on, by a high voltage pulse on the row conductor, a signal from the column conductor is allowed to pass on to an area of liquid crystal material (or other capacitive display cell), thereby altering the light transmission characteristics of the material.

It is well known to provide an additional storage capacitor as part of the pixel configuration to enable a voltage to be maintained on the liquid crystal material even after removal of the row electrode pulse.

The frame (field) period for active matrix display devices requires a row of pixels to be addressed in a short period of time, and this in turn imposes a requirement on the current driving capabilities of the transistor in order to charge or discharge the liquid crystal material to the desired voltage level. In order to meet these current requirements, the gate voltage supplied to the thin film transistor needs large voltage swings. For example, in a display using low temperature polysilicon transistors, the minimum row drive voltage may be around −2 Volts and the maximum around 15 Volts. This ensures the transistor is biased sufficiently to provide the required source-drain current to charge or discharge the liquid crystal material sufficiently rapidly.

The requirement for large voltage swings in the row conductors requires the row driver circuitry to be implemented using high voltage components. It also results in relatively high power consumption.

The use of digital data to control the brightness of pixels within an active matrix display is also of increasing interest. The integration of dynamic memory within the pixels of active matrix displays has also been proposed, in which a digital data value for each pixel is stored in the pixel. Digital data supplied to or stored within the pixels of the display can then be used to select one of a number of different signal voltage waveforms. The selected waveform can then be used either directly or indirectly to drive the display element, for example the liquid crystal pixel element in the case of an active matrix LCD.

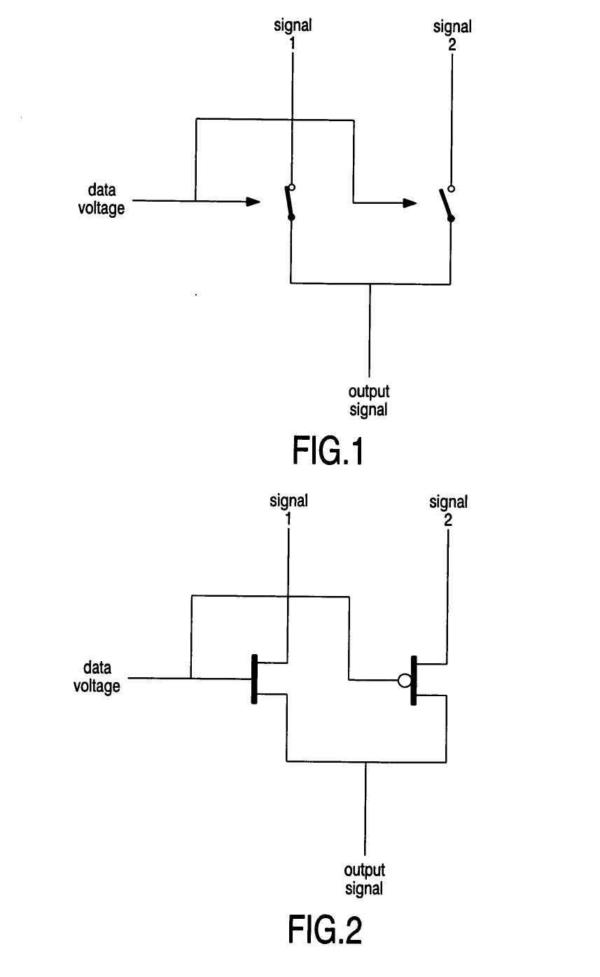

FIG. 1 shows one possible arrangement which allows one of two signal voltage waveforms to be connected to the output of the circuit depending on the state of the data voltage input. When used to route signal to a display element, one of these signals may cause the display element to switch into a dark state while the other may switch the display element into a light state. In a practical circuit, the switches are replaced by thin film transistors.

The area which is available for the circuits within the pixels of a display is limited by the dimensions of the pixel and, in the case of a transmissive display, the need to minimise the area of the pixel where the passage of light through the display is obscured by circuitry. An example of a switching circuit which minimises the number of transistors required is shown in FIG. 2. The output signal can be connected directly to the liquid crystal display element.

In this circuit, the switch connected to signal voltage 1 is implemented as an n-type TFT and the switch connected to signal voltage 2 is implemented as a p-type TFT. The complementary behaviour of the n-type and p-type devices means that with appropriate data voltage levels the circuit can be switched between two states. In one state, the n-type device is conducting and the p-type device is non-conducting, and in the other state the n-type device is non-conducting and the p-type device is conducting.

In order to illustrate the operation of the this circuit, we can consider two examples of the drive voltage waveforms which might be applied to the circuit and the data voltage levels that are required to switch the transistors between the two states.

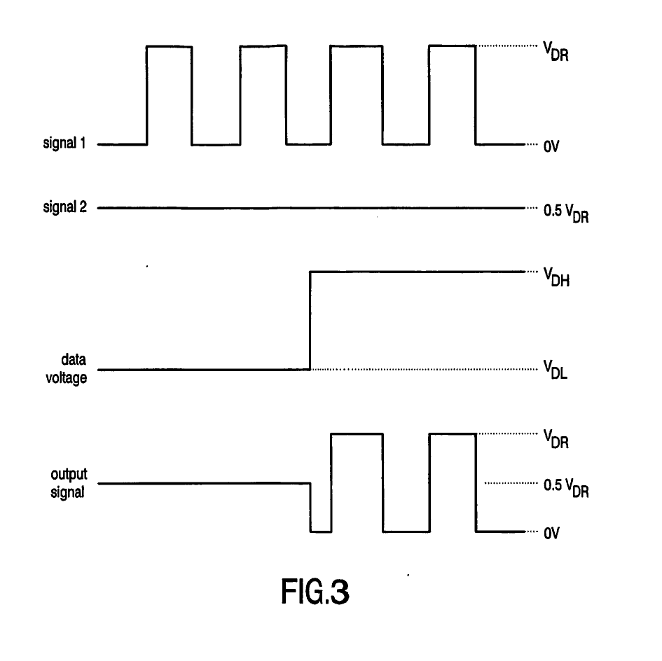

A first example of possible voltage waveforms in shown in FIG. 3. In this example it is assumed that an alternating voltage waveform is applied to the input signal 1. This waveform switches between two voltages levels, 0V and V_{DR}. A constant voltage equal to 0.5V_{DR} is applied to the input signal 2. The voltage applied to the data voltage input is initially at a low level, V_{DL}, and then switches to a high level, V_{DH}. When the data voltage is low, signal 2 is transferred to the output terminal of the circuit. When the data voltage is high, signal 1 is transferred to the output terminal of the circuit. The conditions which determine the maximum allowable value of V_{DL} and the minimum allowable value of V_{DH} are summarised in Table 1 below.

TABLE 1

| Data | Required | Equation for | Values for | | Required |
|---|---|---|---|---|---|
| volt- | Conditions for | required data | specified | | data |
| age | TFT switching | voltages | conditions | | voltage |
| V_{DH} | n-type TFT on | V_{DH} ≧ V_{DR} + Vₙₒₙ | ≧13 | V | 13 V |
| | p-type TFT off | V_{DH} ≧ 0.5 V_{DR} − V_{poff} | ≧4.5 | V | |
| V_{DL} | n-type TFT off | V_{DL} ≦ 0 − V_{noff} | ≦0 | V | 0 V |
| | p-type TFT on | V_{DL} ≦ 0.5 V_{DR} + Vₚₒₙ | ≦0.5 | V | |

In this table, Vₙₒₙ is the gate-source voltage on the n-type TFT required to make the device sufficiently conducting, V_{noff} is the gate-source voltage on the n-type TFT required to make the device sufficiently non-conducting. Vₚₒₙ and V_{poff} are the equivalent parameters for the p-type TFT. The data voltage levels have been calculated for the condition when Vₙₒₙ=4V, Vₚₒₙ=−4V, V_{noff}=0V, V_{poff}=0V, V_{DR}=9V. These values are typical of those that would be required for low temperature poly-Si TFTs and a twisted nematic liquid crystal display element. The minimum value of the high level data voltage is determined by the need to ensure that the n-type TFT remains conducting when the voltage applied to the signal 1 input is at its highest level. The maximum low level data voltage is determined by the need to ensure that the n-type TFT remains in the non-conducting state even when the voltage applied to the signal 1 input is at its lowest level. The amplitude of the data voltage that is required is large, greater than or equal to 13V. Such a high value is undesirable as it will increase the power consumption of the display.

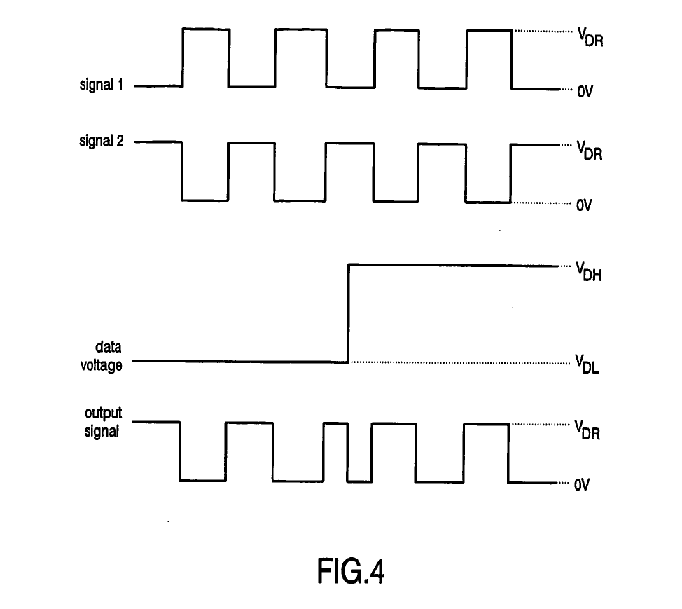

A second example of possible waveforms is shown in FIG. 4. In this example, complementary alternating voltage waveforms are applied to the two signal inputs of the circuit. These waveforms may be appropriate for the so-called common electrode drive scheme, in which an alternating voltage is applied to the common electrode of the display. Thus, signal 1 may be the signal required to drive the pixel to a bright state, and signal 2 may be the signal required to drive the pixel to a dark state (as will be explained further below). The data voltage is again stepped from a low level to a high level and the output signal is equal to signal 2 when the data voltage is low, and signal 1 when the data voltage is high. The conditions which define the required value of data voltage are indicated in Table 2. The values of Vₙₒₙ, V_{noff}, Vₚₒₙ and V_{poff} are the same as in the first example and V_{DR} has a value of 4.5V.

TABLE 2

| Data | Required | Equation for | Values for | | Required |
|---|---|---|---|---|---|
| volt- | Conditions for | required data | specified | | data |
| age | TFT switching | voltages | conditions | | voltage |
| V_{DH} | n-type TFT on | V_{DH} ≧ V_{DR} + Vₙₒₙ | ≧8.5 | V | 8.5 V |
| | p-type TFT off | V_{DH} ≧ V_{DR} − V_{poff} | ≧4.5 | V | |
| V_{DL} | n-type TFT off | V_{DL} ≦ 0 − V_{noff} | ≦0 | V | −4 V |
| | p-type TFT on | V_{DL} ≦ 0 + Vₚₒₙ | ≦−4 | V | |

The amplitude of the data voltage that is required is determined by the voltages needed to turn on either the n-type or the p-type TFT. The minimum high level of the data voltage is that which is required to turn the n-type device on when signal 1 is at its maximum level. The maximum low level of the data voltage is that required to turn on the p-type device when signal 2 is at its minimum voltage level. The required data voltage amplitude is again relatively large, greater than or equal to 12.5V.

If the output signal of the circuit is being used to drive a liquid crystal display element, then the common electrode of the display would be carry an alternating signal with an amplitude and phase equal to that of signal 2, but with an adjusted dc voltage level. The voltage appearing across the display element is then derived from the difference between the output signal of the switching circuit and signal 2. This voltage would have a peak to peak value of zero when the data voltage is low and 2V_{DR} when the data voltage is high.

If the swing in the data voltage could be reduced, this would enable a reduction in power consumption. This may, for example, be appropriate for a low power stand-by mode.

According to the invention, there is provided a device comprising an array of pixels, each pixel including a pixel element and being associated with a switching circuit, wherein the switching circuit is for selectively routing one of at least two inputs to the pixel element, comprising at least first and second switching transistors connected between a respective one of the at least two inputs and the pixel element, wherein each switching transistor is controlled by a data signal applied to the gate of the transistor, wherein the data signal for each switching transistor is routed to the gate of the switching transistor with predetermined timing determined in dependence on the data waveform of at least one of the inputs, and wherein a capacitive connection is provided between the gate of at least one of the switching transistors and an output of the switching transistor.

The invention enables a reduction in the data voltage range which is required to ensure that the switching transistors switch correctly, by using a bootstrapping technique. In particular, by controlling the timing of application of the data signals for switching on or off the switching transistors, the voltage levels of at least one of the input signals can be used to provide capacitive coupling through the respective switching transistor onto the bootstrapping capacitor (the “capacitive connection”).

The term “connected between” an input and an output in connection with a switch is not intended to indicate direct connection of the output of the switch to the output, merely that the output of the switch is in turn coupled to the output, whether directly or through other switches or capacitive connections. Indeed, the output is eventually the pixel element, as the switching circuit is for routing one of a number of signals to the pixel element, but there are other components between the switching transistors and the pixel element.

The array device of the invention can have the switching circuits integrated into each pixel, for selectively routing one of at least two inputs to the pixel element. The switching circuits may, however, be partially provided in peripheral address circuitry instead of purely integrated into the pixel area, or the switching circuit may be provided entirely in the address circuitry.

The data signal for each switching transistor can be routed to the gate of the switching transistor by a transfer switch which controls the timing of application of the data signal for each switching transistor, and wherein a capacitive connection is provided between the gate of each switching transistor and the output of each switching transistor. The (or each) transfer switch allows the transistor gates to float after application of the data signal.

A capacitive connection is for example provided between the gate of each switching transistor and a common output of the switching circuit.

The gates of the first and second switching transistors may be connected together and the capacitive connection comprises a capacitor connected between the gates and the common output. In this way, the bootstrapping capacitor can be shared between the two inputs. The first switching transistor can be an n-type transistor and the second switching transistor can be a p-type transistor. This enables a single data signal to be applied to the gates of both switching transistors to simultaneously switch one transistor on and the other off, with a reduced voltage swing between the on and off voltage levels of the data signal.

Instead, the capacitive connection may comprise a respective capacitor connected between the gate of each switching transistor and the common output. Each transistor may then be individually switchable.

The circuit may comprising n inputs, where n is greater than 2, and comprise first to nth switching transistors connected between a respective one of the n inputs and the pixel element, and wherein the data signals for each switching transistor are selected such that an individual one of the switching transistors is turned on to route the respective input to the pixel element. This provides a one-of-n selection circuit. In this arrangement, some switching transistors can be n-type and others p-type, or they may all be the same.

The circuit may comprise n inputs, but with first to nth switching transistors connected between a respective one of the n inputs and one of two intermediate outputs, and wherein the data signals for each switching transistor are selected such that half of the switching transistors are turned on to route a first selected input to one intermediate output and to route a second selected input to the other intermediate output. This arrangement provides two channels in parallel, with an input selected for each channel. This can form the building block for a selector circuit using a binary word as the control signal. For example, a further switching circuit can selectively route one of the intermediate outputs inputs to the common output, namely the pixel, and this can provide a one of four selector controlled by a two bit word.

The device of the invention can be an active matrix display device. The display device may comprise an array of pixels, each pixel comprising:
the switching circuit of the invention for routing one of (at least) two voltage drive levels to a common output;
a first selection switch between the common output and the liquid crystal cell of the pixel; and
a second selection switch between an analogue pixel data line and the liquid crystal cell of the pixel.

In this arrangement, the switching circuit can select between bright and dark, for a low power mode of operation in which low voltages are needed. This mode of operation is selected by the first selection switch. However, the display can also be used in a normal analogue mode, and this mode is selected by the second selection switch.

The control signal for selecting which one of the two voltage drive levels is to be routed to the common output can be provided on the analogue pixel data line, which is thus shared between the two modes of operation.

The invention also provides a method of routing one of at least two inputs to a pixel element within a pixel of a device comprising an array of pixels, the method comprising:
applying data signals to the gates of at least first and second switching transistors connected between a respective one of the at least two inputs and the pixel element to turn on a selected one of the first and second switching transistors and turn off the other of the first and second switching transistor, thereby routing the respective input to the pixel element,
wherein the timing of application of the data signals is selected in dependence on the signals on at least one of the two inputs,
wherein a capacitive connection is provided between the gate of at least one switching transistor and an output of the switching transistor, and
wherein the timing is controlled such that the capacitive connection reduces the required voltage swing in the data signal between that required to turn on and turn off a switching transistor.

This method can be used in driving of a liquid crystal display. In a first mode, analogue pixel drive signals can be switched to each pixel of the display (normal mode) and in a second mode, the method of the invention can be used for routing one of two pixel drive signals (bright or dark) on respective inputs to each pixel of the display (digital low power mode).

Examples of the invention will now be described in detail with reference to the accompanying drawings, in which:

FIG. 1 shows schematically a known switching circuit for selecting one of two inputs;

FIG. 2 shows an implementation of the circuit of FIG. 1;

FIGS. 3 and 4 show different waveforms for controlling the circuit of FIG. 2;

FIG. 5 shows one example of a known pixel configuration for an active matrix liquid crystal display;

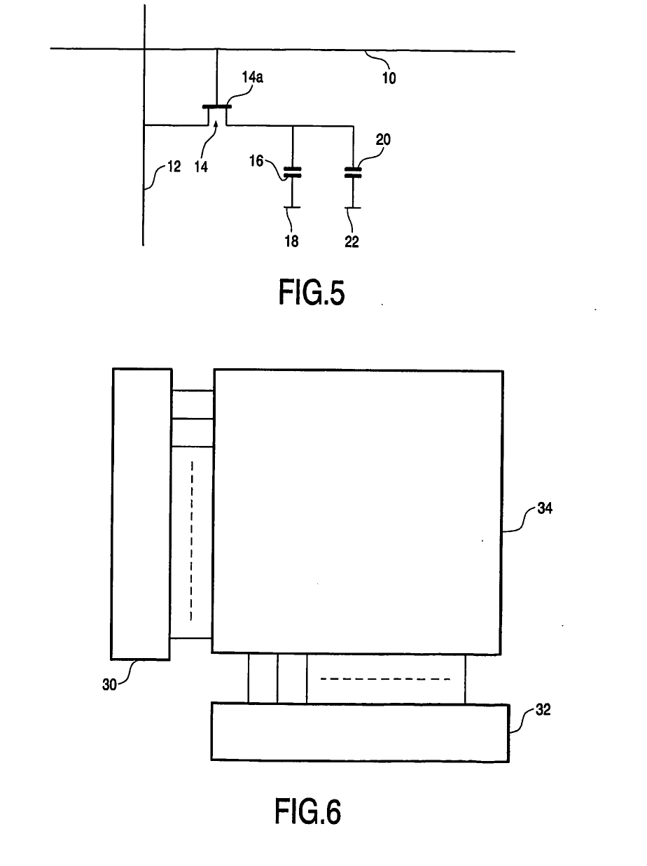

FIG. 6 shows a display device including row and column driver circuitry;

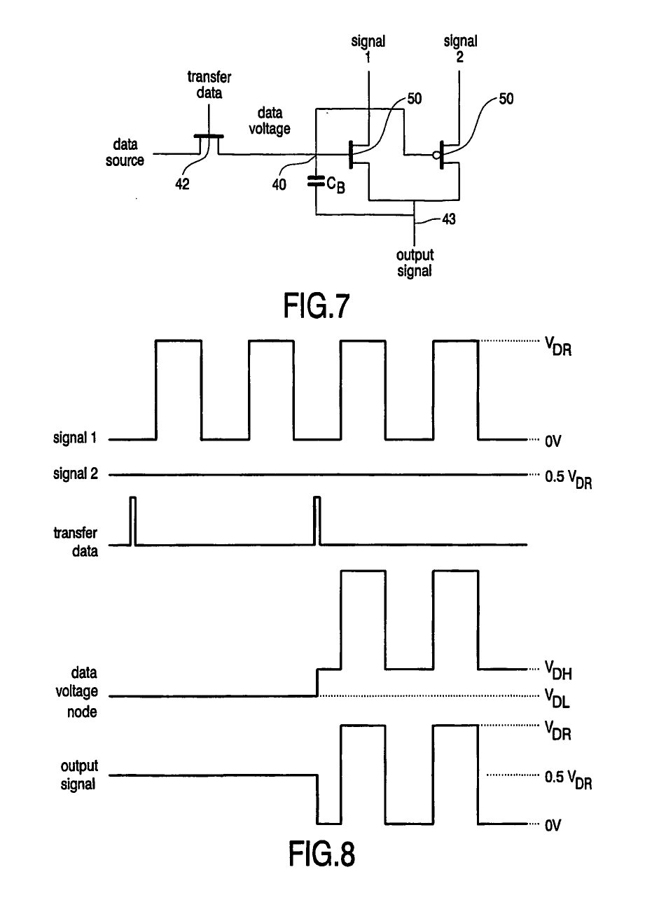

FIG. 7 shows a first example of switching circuit of the invention;

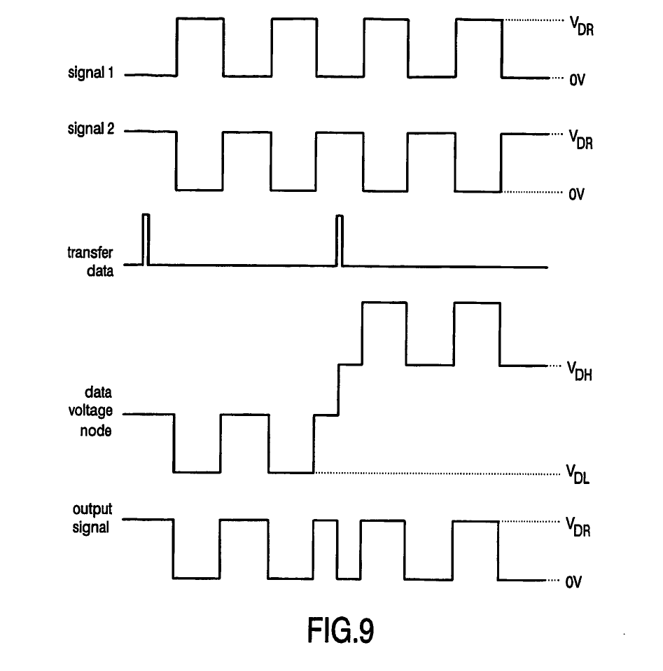

FIGS. 8 and 9 show different waveforms for controlling the circuit of FIG. 7;

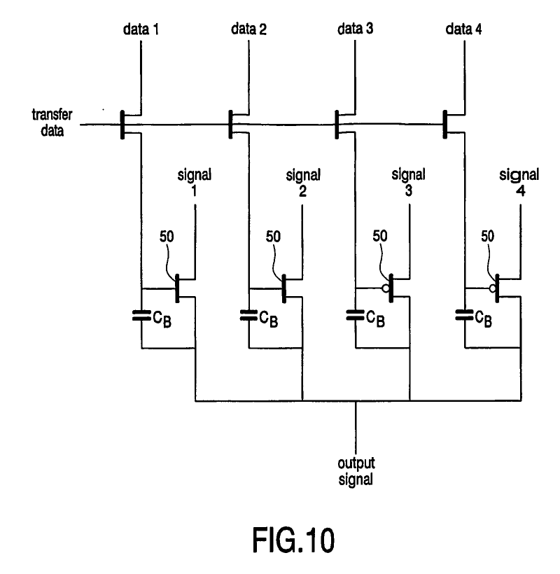

FIG. 10 shows a second example of switching circuit of the invention;

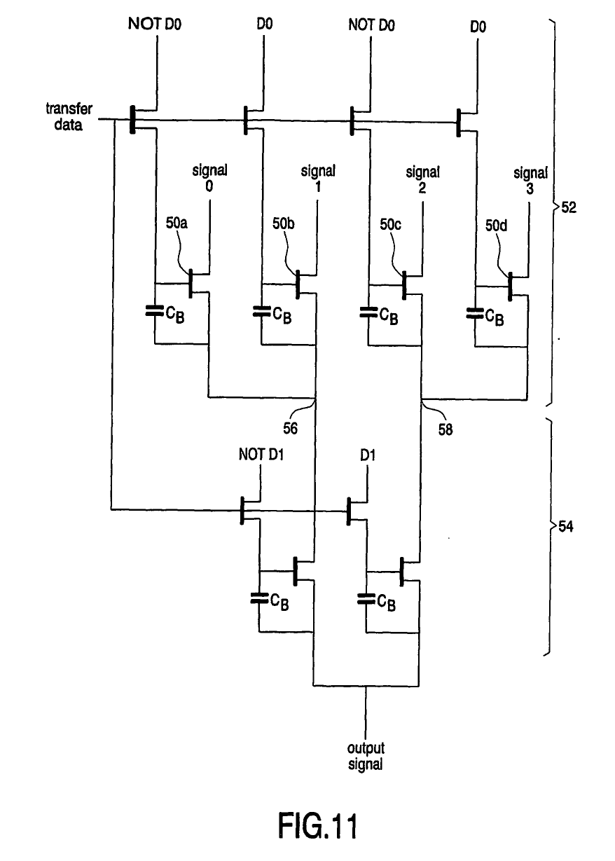

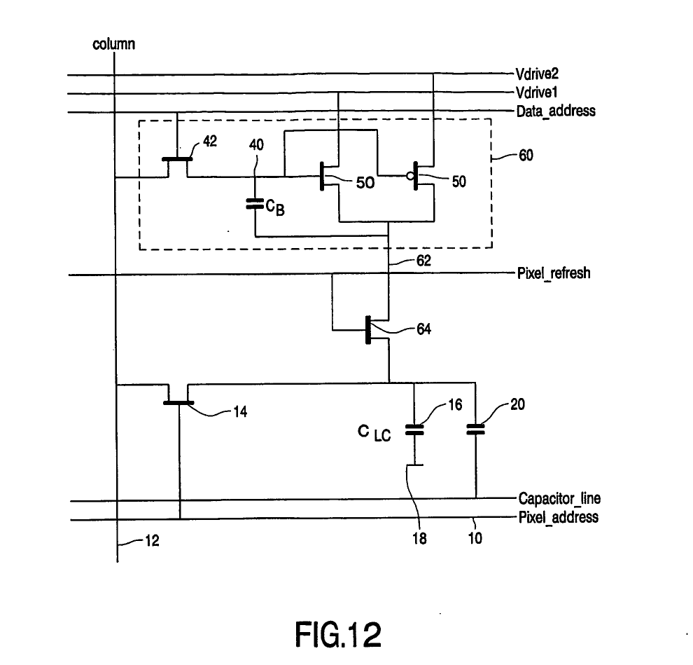

FIG. 11 shows a third example of switching circuit of the invention;

FIG. 12 shows a first example of circuit of the invention used within a pixel of an active matrix display;

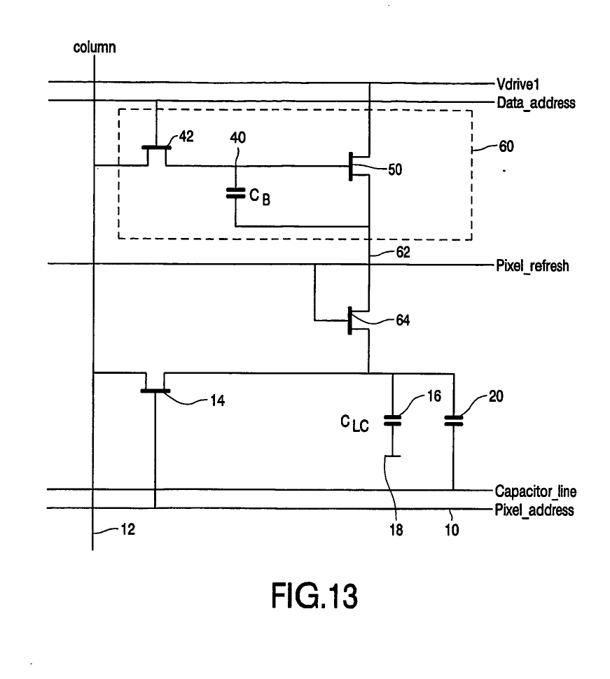

FIG. 13 shows a second example of circuit of the invention used within a pixel of an active matrix display; and

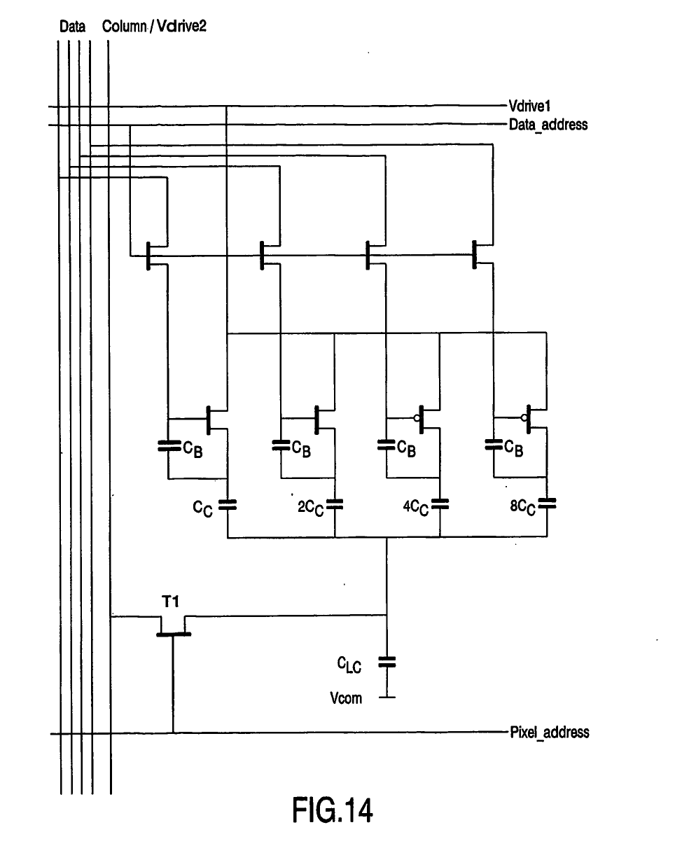

FIG. 14 shows a third example of circuit of the invention used within a pixel of an active matrix display.

FIG. 5 shows a conventional pixel configuration for an active matrix liquid crystal display. The display is arranged as an array of pixels in rows and columns. Each row of pixels shares a common row conductor 10, and each column of pixels shares a common column conductor 12. Each pixel comprises a thin film transistor 14 and a liquid crystal cell 16 arranged in series between the column conductor 12 and a common electrode 18. The transistor 14 is switched on and off by a signal provided on the row conductor 10. The row conductor 10 is thus connected to the gate 14a of each transistor 14 of the associated row of pixels. Each pixel additionally comprises a storage capacitor 20 which is connected at one end 22 to the next row electrode, to the preceding row electrode, or to a separate capacitor electrode. This capacitor 20 stores a drive voltage so that a signal is maintained across the liquid crystal cell 16 even after the transistor 14 has been turned off.

In order to drive the liquid crystal cell 16 to a desired voltage to obtain a required gray level (which may be simply black or white), an appropriate signal is provided on the column conductor 12 in synchronism with a row address pulse on the row conductor 10. This row address pulse turns on the thin film transistor 14, thereby allowing the column conductor 12 to charge the liquid crystal cell 16 to the desired voltage, and also to charge the storage capacitor 20 to the same voltage. At the end of the row address pulse, the transistor 14 is turned off, and the storage capacitor 20 maintains a voltage across the cell 16 when other rows are being addressed. The storage capacitor 20 reduces the effect of liquid crystal leakage and reduces the percentage variation in the pixel capacitance caused by the voltage dependency of the liquid crystal cell capacitance.

The rows are addressed sequentially so that all rows are addressed in one frame period, and refreshed in subsequent frame periods.

As shown in FIG. 6, the row address signals are provided by row driver circuitry 30, and the pixel drive signals are provided by column address circuitry 32, to the array 34 of display pixels.

In order to enable a sufficient current to be driven through the thin film transistor 14, which is implemented as an amorphous silicon or polycrystalline silicon thin film device, a high gate voltage must be used. In particular, the period during which the transistor is turned on is approximately equal to the total frame period within which the display must be refreshed, divided by the number of rows. The gate voltage for the on-state and the off-state differ by approximately 12 Volts for polysilicon displays in order to provide the required small leakage current in the off-state, and sufficient current flow in the on-state to charge or discharge the liquid crystal cell 16 within the available time.

FIG. 7 shows a first switch arrangement in accordance with the invention, in which the voltage swing on the signal required to drive the circuit between the two possible states is reduced. The implementation of the switching circuit into an array device will be described further below.

As shown, a capacitor, C_{B}, is connected between data voltage node 40 and the output signal node 43. The two switching transistors 50 are of opposite polarity type. When the data voltage is applied to the data voltage node 40 by means of a transfer switch 42, the input signals are held at voltage levels which maximise the gate-source voltage present on the TFT which is to be turned on. This implies that the signal connected to the input of the n-type TFT, signal 1, should be at its lowest voltage level and the signal at the input of the p-type TFT, signal 2, should be at its highest voltage level. The data voltage node is then isolated from the source of data by the transfer switch 42 and the data voltage is held on the capacitor C_{B}. Any changes in the output signal voltage are coupled onto the data voltage node thus maintaining the gate-source voltage of the device which is conducting. The advantage of this can be illustrated by considering the two sets of example waveforms used in the analysis above.

FIG. 8 shows how the waveforms of FIG. 3 can be modified to suit the pixel arrangement of FIG. 7, which uses the bootstrap capacitor C_{B}. A new waveform, “transfer data”, has been added. When this signal is high, the data voltage level is transferred to the data voltage node 40 from the data source. When the signal is low, the data voltage node 40 is isolated from the data source. This function can be achieved using a TFT switch as indicated in FIG. 7. The effect of introducing the capacitor C_{B} into the switching circuit is to modify the voltage waveform appearing on the data voltage node. The data voltage required to switch on the n-type device can be minimised if the data voltage is transferred from the data source when the voltage present at the signal 1 input is at its minimum level. Thus, the second pulse in the “transfer data” waveform is timed to correspond to a trough in the “signal 1” waveform.

The required data voltage levels for switching the two transistors are summarised in Table 3.

TABLE 3

| Data | Required | Equation for | Values for | Required |
|---|---|---|---|---|
| volt- | Conditions for | required data | specified | data |
| age | TFT switching | voltages | conditions | voltage |
| V_{DH} | n-type TFT on | V_{DH} ≧ 0 + Vₙₒₙ | ≧4 V | 4.5 V |
| | p-type TFT off | V_{DH} ≧ 0.5 V_{DR} − V_{poff} | ≧4.5 V | |
| V_{DL} | n-type TFT off | V_{DL} ≦ 0 − V_{noff} | ≦0 V | 0 V |
| | p-type TFT on | V_{DL} ≦ 0.5 V_{DR} + Vₚₒₙ | ≦0.5 V | |

The switching conditions for the p-type device are unchanged from the previous case when C_{B} was not present. However, the high data voltage level required to turn on the n-type transistor is now reduced. Signal 1 is at 0V when the data voltage is transferred to the data voltage node and therefore a data voltage of Vₙₒₙ is sufficient to turn on the n-type device. When the voltage applied to the signal 1 input changes to a level V_{DR} this change in voltage is coupled onto the data voltage node by C_{B} since the data voltage node is now isolated from the data source. The voltage on the gate of the TFTs increases to approximately V_{DH}+V_{DR} which will ensure that the n-type device remains in a conducting state in spite of the increased voltage at its source and drain terminals. The consequence of this bootstrapping effect is that the high level data voltage required to switch the n-type device is only 4V. This is less than the high level voltage required to maintain the p-type device in a non-conducting state and therefore for the specific values used in this example the minimum required high data voltage level is 4.5V. In practice, the bootstrapping effect of C_{B} will not be perfect due to the presence of other capacitances at the data voltage node. The effect of these capacitances will be to make the change in the voltage on the gate of the transistor smaller than the change in voltage on the source. The gate-source voltage will therefore decrease as the signal voltage increases and the transistor will become less conducting. This may necessitate the use of a somewhat higher data voltage than is predicted by this simple analysis.

This example illustrates that by introducing the capacitor C_{B} into the switching circuit and by transferring the data voltage to the data voltage node when the signal voltage is at an optimum level and then isolating that node, a substantial reduction in the required data voltage range can be achieved, thus reducing the power consumption of the display.

FIG. 9 shows how the waveforms of FIG. 4 can be modified to suit the pixel arrangement of FIG. 7, which uses the bootstrap capacitor C_{B}. The “transfer data” waveform again indicates the time when the data voltage is transferred to the data voltage node. By transferring the data voltage to the data voltage node when signal 1 is at its minimum level and signal 2 is at its maximum level it is possible to reduce the difference between the high and low data voltage levels required to switch the p-type and n-type TFTs. As in the previous example, the effect of C_{B} is to couple changes in the output voltage onto the data voltage node following the isolation of the data voltage node from the data voltage source. In the case when the data voltage is initially at the low level, V_{DL}, when signal 2 goes to its minimum value, the output drive voltage falls to the same level and the capacitor C_{B} will couple this change in voltage onto the data voltage node. This ensures that the p-type device remains in a conducting state. In the case when the data voltage is initially at the high level, V_{DH}, when signal 1 goes to its maximum value the output drive voltage rises to the same level and the capacitor C_{B} will couple this change in voltage onto the data voltage node ensuring that the n-type device remains in a conducting state. The data voltage requirements for the switching circuit including C_{B} are summarised in Table 4.

TABLE 4

| Data | Required | Equation for | Values for | Required |
|---|---|---|---|---|
| volt- | Conditions for | required data | specified | data |
| age | TFT switching | voltages | conditions | voltage |
| V_{DH} | n-type TFT on | V_{DH} ≧ 0 + Vₙₒₙ | ≧4 V | 4 V |
| | p-type TFT off | V_{DH} ≧ V_{DR} − V_{poff} | ≧3.5 V | |
| V_{DL} | n-type TFT off | V_{DL} ≦ 0 − V_{noff} | ≦0 V | −0.5 V |
| | p-type TFT on | V_{DL} ≦ V_{DR} + Vₚₒₙ | ≦−0.5 V | |

The required data voltage amplitude for the stated conditions is determined by the need to ensure that the n-type and p-type TFTs remain conducting when the input drive waveforms switch. The data signal amplitude is again substantially reduced by the introduction of the capacitor C_{B} to a value of 4.5V.

It will be seen that this implementation of the invention provides a method of selecting, routing or multiplexing signals using a network of p-type or n-type thin film transistors. The bootstrapping technique, in which the output signal of the switching transistor is capacitively coupled onto its gate, allows relatively low data or control signal voltages to be used to control the transistors. The correct operation of the circuit requires some knowledge of the signal characteristics since it is preferable to transfer the control data to the transistors when the signal voltages that they are passing are at their maximum (most positive) or minimum (most negative) voltage level for p-type and n-type devices respectively. This approach minimises the voltage range of the signals used to control the switches.

If the signal voltage passed by a TFT has a minimum level of Vₘᵢₙ and a maximum level of Vₘₐₓ then the data or control voltage levels required to switch the device using a conventional approach and the proposed bootstrapped approach are as indicated in Table 5 for an n-type device and Table 6 for a p-type device. It is assumed that the ratio of the bootstrapping capacitor C_{B} to the total capacitance of the data voltage node is equal to k_{B}.

TABLE 5

| | Required | Data voltages | Equations for data |
|---|---|---|---|
| Data | Conditions for | without | voltages with |
| voltage | TFT switching | bootstrapping | bootstrapping |
| High | n-type TFT on | V_{DH} ≧ Vₘₐₓ + Vₙₒₙ | V_{DH} ≧ Vₘₐₓ + Vₙₒₙ − k_{B}(Vₘₐₓ − Vₘᵢₙ) |
| level | | | |
| Low | n-type TFT off | V_{DL ≦ V}ₘᵢₙ − V_{noff} | V_{DL} ≦ Vₘᵢₙ − V_{noff} |
| level | | | |

TABLE 6

| | Required | Data voltages | Equations for data |
|---|---|---|---|
| Data | Conditions for | without | voltages with |
| voltage | TFT switching | bootstrapping | bootstrapping |
| Low | p-type TFT on | V_{DL} ≦ Vₘᵢₙ + Vₚₒₙ | V_{DL} ≦ Vₘᵢₙ + Vₚₒₙ + k_{B}(Vₘₐₓ − Vₘᵢₙ) |
| level | | | |
| High | p-type TFT off | V_{DH} ≧ Vₘₐₓ − V_{poff} | V_{DH} ≧ Vₘₐₓ − V_{poff} |
| level | | | |

The examples above show that the bootstrapping technique could be applied to a one of two signal selection function. However, the invention can also be applied to other arrangements of switching transistors.

FIG. 10 shows an example of a one of four selection circuit. The control signals “data 1” to “data 4” are generated in such a way as to turn on one of the four switching transistors 50. A combination of p-type and n-type TFT switches can be used as shown in FIG. 10 although transistors of the same type may be used.

FIG. 11 is an example of a two bit voltage selector. This makes use of series-connected switching transistors to provide a decoding and signal switching function.

The switching circuit has 4 inputs (“signal 0” to “signal 3”), and the selection of one of these is by a two bit control signal D0, D1. The circuit has two layer 52, 54. The first layer 52 has first to fourth switching transistors 50a-50d connected between a respective one of the inputs and one of two intermediate outputs 56, 58. The first layer 52 is controlled by one of the bits D0 of the two bit word, and this bit determines which two of the signal inputs are routed to the intermediate outputs. The second layer 54 selectively routes one of the intermediate outputs as the output signal, and is controlled by the other bit D1 of the control signal. The circuit of FIG. 11 is thus formed as a cascade of one-of-two selection circuits.

The circuit of the invention can be used in numerous applications. Essentially, the application requires the input signal waveforms to be known, so that the timing of the “transfer data” signal can be selected to take advantage of the capacitive coupling of the bootstrap capacitors. The invention enables reduced switching voltage levels, and can be used in multiplexer circuits as well as a range of array-type circuit configurations.

One particularly advantageous use of the circuit of the invention is in active matrix display devices, in particular integrated into the pixel design. The circuit can then provide selection between two brightness levels for example for a low power binary display mode. The invention is also particularly suited to displays with integrated memory capability, as described below.

An example of a pixel circuit for an AMLCD which makes use of the circuit of the invention is shown in FIG. 12. The pixel includes the standard pixel circuitry of FIG. 5, and the same reference numerals are used for the same components as in FIG. 5. These components enable the pixel to be operated in the normal analogue drive mode. This may be considered as a first mode of operation.

The pixel also includes a switching circuit 60 corresponding to that described with reference to FIG. 7. Again, the same reference numerals are used for the same components as in FIG. 7. This switching circuit 60 enables selection between two drive voltage levels “Vdrive1” and “Vdrive2” shared between all pixels. The transfer switch 42, which controls the timing of application of the data signal to the gates of the switching transistors, is controlled by a “Data_address” line, which is shared between rows of pixels. The selected drive signal is coupled between the common output 62 of the switching circuit 60 and the liquid crystal cell 16 by a first selection switch 64, which is controlled by a “Pixel_refresh” line, the function of which will be described below. The transistor 14 may be considered as a second transfer switch, and these two transfer switches dictate which part of the pixel (either the analogue or the binary part) supplies the drive signal to the liquid crystal cell 16.

The pixel can, thus, be operated in two modes. In the first analogue mode, the Pixel_refresh electrode is held at a low level so that the display element is isolated from the switching circuit 60 by the first transfer switch 64. In a second operating mode, a digital data signal is applied to the column 12. One bit of data is transferred from the column electrode 12 to the data voltage node 40 by applying a positive going pulse to the Data_address line. This turns on the transfer switch 42 and allows the bootstrapping capacitor C_{B} to be charged.

The bootstrapping capacitor can also act as a capacitance on which the digital data is stored within the pixel. As discussed above, this data transfer is carried out when the signal Vdrive1 is at its minimum voltage level and the signal Vdrive 2 is at its maximum voltage level (as explained with reference to FIG. 9), in order to minimise the range of the digital data voltage that is required to switch the switching transistors 50. After the data has been transferred to the data voltage node, one of the switching transistors 50 will be in a conducting state, and the other device will be in a non-conducting state. Therefore one of the two signals, Vdrive1 and Vdrive2, appears at the output 62 of the switching circuit.

This drive signal is periodically applied to the display element, for example every 20 ms, by applying a positive going pulse to the Pixel_refresh line and turning on the first transfer switch 64.

As mentioned above, the bootstrapping capacitor can function as an integrated memory element. In particular, the capacitor will be charged to different levels depending which of the two signal inputs is switched to the common output. Integrated memory capability has been proposed, as a significant fraction of the power consumption of an active matrix display device is associated with transferring video information from the video signal source to the pixels of the display device. This component of the power can be reduced if the pixels of the display device are able to store the video information for an indefinite period of time. In this case the addressing of the pixels with fresh video information can be suspended when no change to the display output (brightness) state of pixels is required.

Incorporating memory into the pixels of an active matrix display device can thus reduce power when a static image display is permitted because data need only be sent to the display pixels when the image changes and less power is, therefore, consumed in external circuits and in driving the capacitance associated with connections to the display pixels. The pixel circuit of the invention enables a black and white image to be displayed in this low power mode with reduced addressing voltage levels.

When the capacitor is used as a memory element, the digital data which is held on C_{B} must be refreshed periodically since switch 64 and C_{B} effectively form a one bit dynamic memory cell. This refreshing can be achieved by transferring data from an external memory via the column drive circuit and the column electrodes of the display. Alternatively, it might be achieved by reading out the stored data onto the column electrode via the transistors 14 and 64 and making use of the switching circuit formed by transistors 50 to buffer the data signal. In either case, the reduction in the amplitude of the digital data signals resulting from the bootstrapping technique will reduce the amplitude of the digital signals which must be applied to the columns of the display, and this in turn will reduce the power consumption of the display.

The frequency with which the digital data must be refreshed depends on the value of the capacitor C_{B} and the leakage current through the transfer transistor 42. A frequency in the range 5 Hz to 30 Hz might typically be achievable.

In the examples above, the switching circuit is used to select one of at least two drive voltages and provide these to a common output. The bootstrapping technique can however be applied to an AMLCD pixel circuit with only one drive voltage input being switched using the switching arrangement of the invention. FIG. 13 shows a modification to FIG. 12 for this purpose. In FIG. 13, the same reference numerals are used as in FIG. 12 for the same components.

The pixel circuit of FIG. 13 can be operated in a similar manner to the circuit of FIG. 12 but it has only one switching transistor 50 controlled by the data stored on the bootstrap capacitor CB. When the column data voltage is high, and is routed by the transfer switch 42 to the switching transistor 50, the switching transistor 50 is turned on. When the pixel_refresh line is taken high, the pixel is charged to the level of Vdrive1 through the transfer switch 64.

When the column data voltage is low, the switching transistor 50 is turned off, and when the pixel_refresh line is taken high the pixel voltage remains unchanged. The second pixel drive voltage level that is required in order to switch the pixel into a dark state or a light state can be applied to the pixel by using precharging of the pixel capacitance. The pixel is precharged by applying a precharge voltage (for example similar to Vdrive2 in the pixel circuit example in FIG. 12) to the columns of the display and briefly turning on the pixel address transistor 14 before the transfer switch 64. In this way, if the column data voltage is high then the resulting voltage on the pixel electrode will be Vdrive1 but if the column data voltage is low then the resulting voltage on the pixel electrode will be the precharge voltage (Vdrive2).

In this way, a precharge of Vdrive2 is applied to the pixel just before the pixel is addressed. If the column data voltage is high, this is overridden whereas if the column voltage is low, Vdrive2 stays on the pixel. During the pixel address phase, the transistor 14 is turned off.

In the circuit of FIG. 13, transistor 50 acts as one of the switching transistors of the digital switching circuit and transistor 14 acts as the other. They do not share an immediate common output, but they are effectively connected between each input and the LC cell 16 which is thus effectively the common output. The claims should be construed accordingly.

In this case, the timing of application of the data signal still reduces the required voltage swing of the column data, by timing the Data_address pulse with the minimum voltage of the Vdrive1 signal, which may correspond to signal 1 in FIG. 8. Similarly, the precharge voltage applied to the column for transfer to the pixel through the pixel address transistor 14 may correspond to signal 2 of FIG. 8.

In the examples above, the bootstrap capacitor is connected between the gate of each switching transistor and a common output. However, there may be some situations when the outputs of the switching transistors which select the input signal are not connected directly to a common output node. The pixel circuit of FIG. 14 contains a digital to analogue converter. This operates in a similar way to the pixel circuit of FIG. 13 in that the pixel is precharged to a certain voltage using transistor T1 but then the pixel voltage can be changed by coupling a voltage step from Vdrive1 onto the pixel via the converter capacitors C_{C}.

The magnitude of the voltage coupled onto the pixel will depend on the data voltages on the capacitors C_{B}. Note that the outputs of the switching transistors are connected to a common output node but via the additional series-connected capacitiors. These provide the digital to analogue conversion from the digital word on the “Data” lines.

The techniques underlying the invention could be applied very widely, to any situation where it is desirable to use a combination of p-type transistors, n-type transistors or a combination of both to produce a circuit for routing or selecting signals based on the state of digital control or data signals. As outlined above, the technique is of particular interest for use in displays where dynamic memory integrated within the pixel is used to control its brightness.

The terms “row” and “column” are somewhat arbitrary in the description and claims. These terms are intended to clarify that there is an array of elements with orthogonal lines of elements sharing common connections. Although a row is normally considered to run from side to side of a display and a column to run from top to bottom, the use of these terms is not intended to be limiting in this respect.

Other features of the invention will be apparent to those skilled in the art.

1. A device comprising an array of pixels, each pixel including a pixel element and being associated with a switching circuit, wherein the switching circuit is for selectively routing one of at least two inputs to the pixel element, comprising at least first and second switching transistors connected between a respective one of the at least two inputs and the pixel element, wherein each switching transistor is controlled by a data signal applied to the gate of the transistor, wherein the data signal for each switching transistor is routed to the gate of the switching transistor with predetermined timing determined in dependence on the data waveform of at least one of the inputs, and wherein a capacitive connection is provided between the gate of at least one of the switching transistors and an output of the switching transistor.

2. A device as claimed in claim 1, wherein the data signal for each switching transistor is routed to the gate of the switching transistor by a transfer switch which controls the timing of application of the data signal for each switching transistor, and wherein a capacitive connection is provided between the gate of each switching transistor and the output of each switching transistor.

3. A device as claimed in claim 2, wherein a capacitive connection is provided between the gate of each switching transistor and an output of the switching circuit.

4. A device as claimed in any preceding claim, wherein the gates of the first and second switching transistors are connected together and the capacitive connection comprises a capacitor connected between the gates and an output of the switching circuit.

5. A device as claimed in claim 4, wherein the first switching transistor is an n-type transistor and the second switching transistor is a p-type transistor.

6. A device as claimed in claim 1, wherein the capacitive connection comprises a respective capacitor connected between the gate of each switching transistor and an output of the switching circuit.

7. A device as claimed in claim 6, comprising n inputs, where n is greater than 2, and comprising first to nth switching transistors connected between a respective one of the n inputs and the pixel element, and wherein the data signals for each switching transistor are selected such that an individual one of the switching transistors is turned on to route the respective input to the pixel element.

8. A device as claimed in claim 7, wherein at least one of the switching transistors is n-type and at least one of the switching transistors in p-type.

9. A device as claimed in claim 7, wherein all switching transistors are of the same polarity type.

10. A device as claimed in claim 6, comprising n inputs, and comprising first to nth switching transistors connected between a respective one of the n inputs and one of two intermediate outputs, and wherein the data signals for each switching transistor are selected such that half of the switching transistors are turned on to route a first selected input to one intermediate output and to route a second selected input to the other intermediate output.

11. A device as claimed in claim 10, further comprising a switching circuit for selectively routing one of the intermediate outputs to the pixel element.

12. A device as claimed in claim 1 comprising an active matrix liquid crystal display device in which the pixel elements comprise liquid crystal cells, each pixel comprising the switching circuit for routing one of two voltage drive levels to the pixel element.

13. A device as claimed in claim 12, further comprising:
a first selection switch between the common output of the switching circuit and the liquid crystal cell of the pixel; and
a second selection switch between an analogue pixel data line and the liquid crystal cell of the pixel.

14. A device as claimed in claim 13, wherein the two voltage drive levels comprise voltages for driving the liquid crystal cell to a black and a white state.

15. A device as claimed in claim 13, wherein the control signal for selecting which one of the two voltage drive levels is to be routed to the pixel element is provided on the analogue pixel data line.

16. A device as claimed in claim 15, wherein the data signal for each switching transistor is routed to the gate of the switching transistor by a transfer switch which controls the timing of application of the data signal for each switching transistors, and wherein a capacitive connection is provided between the gate of each switching transistor and the output of each switching transistor, and wherein the transfer switch is provided between the analogue pixel data line and the gates of the first and second switching transistors.

17. A device as claimed in claim 12, further comprising:
a first selection switch between the output of the at least one of the switching transistors and the liquid crystal cell of the pixel; and
a second selection switch between an analogue pixel data line and the liquid crystal cell of the pixel.

18. A device as claimed in claim 17, wherein the second selection switch comprises the other of the first and second switching transistors.

19. A device as claimed in claim 18, wherein in a first mode, the second selection switch provides one of two digital pixel signals from the analogue pixel data line to the liquid crystal cell, and in a second mode the second selection switch provides an analogue pixel signal from the analogue pixel data line to the liquid crystal cell.

20. A method of routing one of at least two inputs to a pixel element within a pixel of a device comprising an array of pixels, the method comprising:
applying data signals to the gates of at least first and second switching transistors connected between a respective one of the at least two inputs and the pixel element to turn on a selected one of the first and second switching transistors and turn off the other of the first and second switching transistors, thereby routing the respective input to the pixel element,
wherein the timing of application of the data signals is selected in dependence on the signals on at least one of the two inputs,
wherein a capacitive connection is provided between the gate of at least one switching transistor and an output of the switching transistor, and
wherein the timing is controlled such that the capacitive connection reduces the required voltage swing in the data signal between that required to turn on and turn off a switching transistor.

21. A method of driving a liquid crystal display, comprising:
in a first mode, switching analogue pixel drive signals to each pixel of the display; and
in a second mode, routing one of two pixel drive signals on respective inputs to each pixel of the display, the routing for each pixel in the second mode using the method of claim 20.
